(19) United States
(12) Patent Application Publication
(10) Pub. No.: US 2024/0428981 A1
(43) Pub. Date: Dec. 26, 2024

(54) FLEXIBLE THREE-DIMENSIONAL ELECTRONIC COMPONENT

(71) Applicant: Liquid Wire Inc., Portland, OR (US)

(72) Inventors: Katherine M. Nelson, Portland, OR (US); Jesse Michael Martinez, Milwaukie, OR (US); Michael Adventure Hopkins, Portland, OR (US)

(21) Appl. No.: 18/700,986

(22) PCT Filed: Oct. 21, 2022
(86) PCT No.: PCT/US2022/078517

§ 371 Date: Apr. 12, 2024

Related U.S. Application Data
(60) Provisional application No. 63/270,589, filed on Oct. 22, 2021.

(51) Int. Cl. H01F 27/28

(52) U.S. Cl. CPC H01F 27/2804

(57) ABSTRACT

An electronic component (102), system. and method includes a substrate portion (106) forming a channel (104) and conductive gel (108) positioned within the channel. The conductive gel is arranged to create an electronic effect of the electronic component. The conductive gel forms a first elongate conductive trace (124) and a second elongate conductive trace (126). the first elongate conductive trace (124) forming a pattern of the electronic component that is mimicked by the second elongate conductive trace (126). The first and second elongate conductive traces have a common two-dimensional projection along a major axis (116) of the electronic component.

### CLAIM OF PRIORITY

This patent application claims the benefit of priority to U.S. Provisional Application Ser. No. 63/270,589, filed Oct. 22, 2021, which is incorporated by reference herein in its entirety.

### BACKGROUND

While certain electronic components often have some inherent flexibility or stretchability, such flexibility and/or stretchability is typically constrained both in the amount the components can flex or stretch, their resilience in flexing or stretching, and the number of times the electronic components can flex or stretch before the electronic components deteriorate or break. Consequently, the utility of such electronic components in various environments may be limited, either by reliability or longevity or by the ability to function at all. For instance, incorporating electronic components into body worn sensors or wearable articles may be challenging because such environments may involve repetitious and/or unusual flexing or stretching of the electronic component.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a three-dimensional cutaway image of an electronic component, in an example embodiment.

FIGS. 2A-2E are depictions of individual layers of a substrate of an electronic component, in an example embodiment

FIGS. 3A-3E are abstract depictions of routing patterns in patterned layers of a laminate structure, in an example embodiment.

FIGS. 4A and 4B are abstract depictions of a bottom routing pattern and a top routing pattern, respectively, in an example embodiment.

FIG. 5 is illustrations of a normalized magnetic field generated by an electronic component when current is passed over conductive gel, in an example embodiment.

### DETAILED DESCRIPTION

Example methods and systems are directed to a three-dimensional electronic component, system, and method. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

While certain electronic components typically have some inherent flexibility, that flexibility is typically constrained both in the amount the components can flex, their resilience in flexing, and the number of times the electronic components can flex before the electronic components deteriorate or break. Consequently, the utility of such electronic components in various environments may be limited, either by reliability or longevity or by the ability to function at all. Moreover, such components provided in a single level or plane of a layered structure may require larger sizing which results packaging constraints and additional stresses placed on the component owing to potentially greater overall stretching or flexing compared to a relatively more compact design.

A flexible, three-dimensional electronic component has been developed that incorporates a flexible substrate and deformable conductor, such as a conductive gel. In an example where the electronic component is an inductor, the inductor includes coils that extend across multiple layers of a flexible substrate. The inductor may also include square coils, which may be relatively more cost effective or feasible to manufacture.

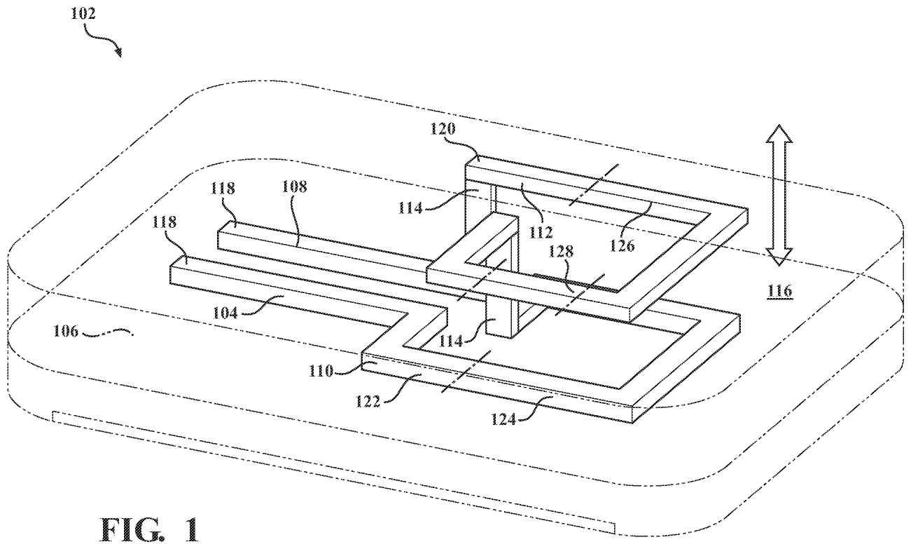

FIG. 1 is a three-dimensional cutaway image of an electronic component 102, in an example embodiment. In the illustrated example the electronic component 102 is a three-dimensional inductor, but it is to be recognized and understood that the principles disclosed with respect to the electronic component 102 may be applicable to creating any suitable electronic component. Moreover, while the electronic component 102 is illustrated with respect to a particular electronic component, i.e., the three-dimensional inductor, it is to be recognized and understood that the electronic component 102 may incorporate multiple individually identifiable components, e.g., capacitors, resistors, transformers, etc., some or all of which may be constructed according to the principles disclosed herein with respect to the example embodiment of the three-dimensional inductor.

In an example, the electronic component 102 includes a channel 104 formed in a medium 106. The channel 104 may be formed according to the techniques described herein or according to any other mechanism that exists or may be developed, including but not limited to injection molding, 3D printing, thermoforming, laser etching, die-cutting, and the like. The medium 106 may be formed of one of: a B-stage resin film, a C-stage resin film, an adhesive, a thermoset epoxy-based film, thermoplastic polyurethane (TPU), and/or silicone, among other suitable compounds or material. In an example, the medium 106 has tensile elongation of 550%; tensile modulus of 5.0 megapascals; recovery rate of 95%; thickness of 100 micrometers; a peel strength at 90 degrees of at least 1.0 kilonewtons per meter; a dielectric constant of 2.3 at 10 gigahertz; a dielectric dissipation factor of 0.0030 at 10 gigahertz; a breakdown voltage of 7.0 kilovolts at a thickness of 80 micrometers; a heat resistance that produces no change in an environment of 260 degrees Celsius for 10 cycles in a nitrogen atmosphere; and chemical resistance producing no change to the medium 106 after 24 hours immersion in any of NaOH, Na2CO3, or copper etchant. Details of an example medium 106 are disclosed in U.S. Patent Application Publication No. 2020/0381349, “CONTINUOUS INTERCONNECTS BETWEEN HETEROGENEOUS MATERIALS”, Ronay et al., which is incorporated by reference herein in its entirety.

In such an example, conductive gel 108 is placed within and contained, at least in part, by the channel 104. Consequently, the conductive gel 108 conforms to the shape of the channel 104, and it is to be recognized and understood that the routing pattern formed by the channel 104 may be mimicked by the conductive gel 108 contained within, and, consequently, that the discussion of the routing of one of the channel 104 and the conductive gel 108 may be understood to refer to the routing of either of the channel 104 and conductive gel 108, or both.

Additionally or in an alternative example, rather than forming the channel 104 and then applying the conductive gel 108 within the channel 104, the conductive gel 108 may be applied on or within the medium 106 and then the medium 106 conformed to the conductive gel 108, resulting in the formation of the channel 104. In such an example, the conductive gel 108 may be applied with flexographic printing within the medium 106 or according to any other suitable technique. Thus, in such an example, the channel 104 conforms to the routing pattern established by the conductive gel 108.

The conductive gel 108 generally forms traces in a first level 110 of the medium 106 and a second level 112 of the medium 106, and a via 114 electrically connecting the conductive gel 108 of the first level 110 to the conductive gel 108 of the second level 112. The conductive gel 108 is generally arranged to provide an electronic effect of the electronic component 102, e.g., in the example of the three-dimensional inductor, an electromagnetic field along a major axis 116 of the electronic component 102. However, various parts of the conductive gel 108 may be arranged to facilitate electronic connection to and within the electronic component 102. Thus, the conductive gel 108 includes terminals 118 and the via 114 which, while they may contribute incidentally or parasitically to the electronic effect of the electronic component 102, are not understood to contribute to the electronic effect of the electronic component 102.

In the illustrated example, in the first level 110 and the second level 112 may include right angles 120 and straight sides 122, subject to the inherent limitations of manufacturing and fabrication technologies. Thus, fractional deviations arising from the manufacturing process that prevent perfectly straight lines and right angles may still be understood for the purposes of this disclosure to be encompassed by the description of the right angles 120 and straight sides 122. The right angles 120 and straight sides 122 provide for a square-loop inductor, in contrast to circular loop inductors that may be created by curved conductors, e.g., as a helix or coil. Optionally, the corners of the right angles 120 may be radiused, rather than sharp corners.

However, while right angles 120 and straight sides 122 are illustrated in FIG. 1, it is to be recognized and understood that the electronic component 102 may be any suitable shape, including but not limited to a variety of geometric shapes. Such geometric shapes may include a curve or curved patterns of the channel 104 and/or the conductive gel 108 in addition to or instead of the right angles 120 and straight sides 122. In various examples, the electronic component 102 may be or include a spiral, helix, coil, or other regular or irregular curved two-dimensional or three-dimensional shapes. In such examples, the electronic component 102 may be formed according to mechanisms that would not necessarily align with the mechanisms described with respect to the illustrated example of FIG. 1, but rather according to any suitable methodology for creating curved routing patterns known or that may be developed in the art.

The electronic component 102 may generally be defined by the substantial, though not necessarily complete, mimicking or overlaying of the routing pattern of the conductive gel 108 in the first level 110 and second level 112 and a common two-dimensional projection of a first elongate conductive trace 124, i.e., a portion of the conductive gel 108 in the first level 110, with that a second elongate conductive trace 126, i.e., a portion of the conductive gel 108 in the second level 112. Consequently, the first elongate conductive trace 124 and second elongate conductive trace 126 occupy a common footprint in their respective levels 110, 112 and, viewed along the major axis 116, would overlap or overlay one another. It is noted that in the illustrated example of the electronic component 102 the first elongate conductive trace 124 and second elongate conductive trace 126 do not include all of the conductive gel 108 in their respective levels 110, 112. Consequently, the first elongate conductive trace 124 and second elongate conductive trace 126 may be defined by the portion of the conductive gel 108 that has a common two-dimensional projection along the major axis 116 and not including the portion of the conductive gel 108 in those levels 110, 112 that does not have a common two-dimensional projection. Such portions are separate by dashed lines 128 in FIG. 1.

While in various examples the routing pattern of the conductive gel 108 in the first level 110 overlays essentially exactly the routing pattern in the second level 112, as illustrated the routing pattern in the first level 110 does not exactly overlay the routing pattern in the second level 112. In certain examples, deviation from exact overlaying between levels 110, 112 may stem in whole or in part from design-for-manufacturing

(“DFM”) considerations to allow the electronic component 102 to be produced with relatively greater reliability and less cost than might otherwise be the case with exact overlays between the routing patterns in the levels 110, 112. Thus, where the routing patterns in the levels 110, 112 terminate, a via 114 may allow current to flow from the first level 110 to the second level 112 and vice versa. In order to do so while respecting DFM guidelines, either or both of the initial and final legs of the routing pattern on the first level 110 and/or the second level 112, respectively, may terminate in an offset relationship to one another, resulting in a mimicking but not a full overlay of the routing patterns between the first level 110 and the second level 112.

The description of the first elongate conductive trace 124 and second elongate conductive trace 126 is not necessarily constrained by the description of the levels 110, 112, and it is to be recognized and understood that the description of the common two-dimensional projection may be agnostic as to the existence of discrete levels or a given number of discrete levels in the medium 106. Thus, in the example of an electronic component 102 forming a helical structure along the major axis 116, all of the conductive gel 108 along the helix may contribute to a common two-dimensional projection. Moreover, while the first elongate conductive trace 124 and second elongate conductive trace 126 of the illustrated example are not contiguous in FIG. 1, and rather are electrically coupled to one another with the via 114 and portions of the conductive gel 108 in the first and second levels 110, 112 not part of the first elongate conductive trace 124 and second elongate conductive trace 126, in the example of the helix the first elongate conductive trace 124 and second elongate conductive trace 126 may be contiguous and the differentiation between the first and second elongate conductive traces 124, 126 at least in part arbitrary.

Moreover, as will be illustrated herein, the number of levels may be greater than two, in which case the magnitude of the electromagnetic field would vary proportionately. In such examples, the routing pattern of an additional layer may overlay substantially exactly the routing pattern of one or the other of the first level 110 and the second level 112. Thus, for instance, a routing pattern of a third level may optionally overlay the routing pattern of the first level 110. It is emphasized, however, that the routing pattern of the third level may not overlay and/or may merely mimic the routing pattern of the first level 110. The same principles may apply to levels beyond a third level.

The mimicking of the first elongate conductive trace 124 with the second elongate conductive trace 126 and resultant common two-dimensional projection along the major axis 116 stands in contrast to, e.g., an incidental crossing of one portion of the channel 104 on the two dimensional projection by another portion of the channel 104. As such, it is to be understood that overlap by one portion of the channel 104 with another portion of the channel 104 on the two-dimensional projection by a length of not more than, in one example, twice the width or thickness of the channel 104 or, in another example, approximately the width or thickness of the channel 104, would not qualify for the purposes of this disclosure as mimicking the pattern of one elongate conductive trace 124, 126 by the other. In another example, it is to be understood that overlap by the channel 104 in the two-dimensional projection from one major feature, e.g., from one right angle 120, to another major feature, e.g., another right angle 120, would qualify as mimicking the pattern of one elongate conductive trace 124, 126 by the other.

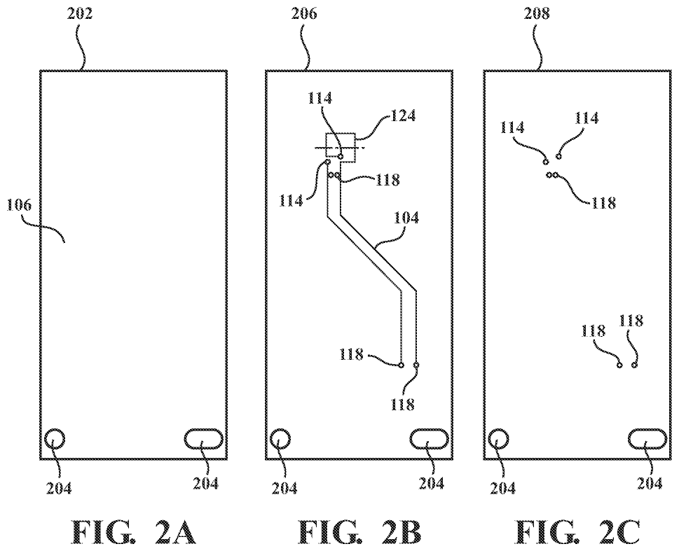

FIGS. 2A-2E are depictions of individual layers of the medium 106 of the electronic component 102, in an example embodiment. In the example of FIGS. 2A-2E, the electronic component 102 is a laminate structure in that individual layers of the medium 106 are separately formed, stacked, and unitized together to create the medium 106 as a whole. The layers may be formed according to iterative stencil-in-place processes described in in U.S. Patent Application Publication No. 2020/0066628, “STRUCTURES WITH DEFORMABLE CONDCUTORS”, Ronay et al., which is incorporated by reference herein in its entirety. or according to any suitable mechanism. However, as noted above, the formation of the electronic component 102 as a laminate structure is for example and not limitation and that any suitable technique for making the electronic component 102 may be applied instead of or in addition to the process of making the electronic component 102 as a laminate structure. The depictions of the layers are looking along the major axis 116 as illustrated in FIG. 1 and are thus either a top or bottom view of the layer relative to the perspective of FIG. 1.

FIG. 2A is substrate layer 202. The substrate layer 202 is formed of the material of the medium 106 and has conductive gel 108 placed thereon but is otherwise featureless and may, in various examples, provide insulation for and/or containment of the conductive gel 108. The substrate layer 202 includes through holes 204 that may not be relevant to the electrical properties of the electronic component 102.

FIG. 2B is a first patterned layer 206. The first patterned layer 206 includes the channel 104 formed in the medium 106 to form various features shown in the first level 110 of FIG. 1, including the terminals 118 and the first elongate conductive trace 124. The terminals 118 may be or may include vias. Terminus points of the channel 104 align with and are operatively coupled to vias 114. Terminals 118 are electrically coupled to respective channels 104 to provide electrical connectivity on a major surface of the electronic component 102.

FIG. 2C is an insulation layer 208. The first encapsulant layer 210 includes the channel 104 formed vertically through the insulation layer 208 to form vias 114. The insulation layer 208 further includes portions of the channel 104 that align with the terminals 118. The terminals 118 extend through the insulation layer 208.

FIG. 2D is a second patterned layer 210. The insulation layer 208 includes the channel 104 formed in the medium 106 to form various features shown in the second level 112 in FIG. 1, including the terminals 118 and the second elongate conductive trace 126. Terminus points of the channel 104 align with vias 114. The terminals 118 extend through the second patterned layer 210. At least one of the terminus points of the first patterned layer 206 aligns with at least one terminus point of the second patterned layer 210. In such an example, the terminus point of the second patterned layer 210 may be understood to function as an origin point and may align with the terminus point of the first patterned layer 206 and are operatively coupled to one another with the via 114.

FIG. 2E is an encapsulant layer 212. The encapsulant layer 212 includes the channel 104 formed into the terminals 118. The encapsulant layer 212 also provides insulation for and/or containment of the conductive gel 108. The terminals 118 extend through the encapsulant layer 212 and provide for electrical connectivity with the conductive gel 108 within the channel 104.

The various layers are presented for illustration and not limitation and it is to be recognized and understood that any of a variety of additional or alternative layers may be incorporated into the laminate structure as desired. The laminate structure may incorporate at least one substrate layer onto which conductive gel 108 is positioned, at least one patterned layer that forms at least one trace, and at least one encapsulation layer that seals the trace or other component of the laminate structure. The laminate structure may further include: a stencil layer, e.g., for when a stencil-in-place manufacturing process is utilized; a conductive layer for, e.g., a relatively high-powered bus, sensor, ground plane, shielding, etc.; an insulation layer, e.g., between a substrate layer, a conductive layer, a stencil layer, and/or an encapsulation layer, that primarily insulates traces or conductive layers from one another; an electronic component not necessarily formed according to the processes disclosed herein, e.g., a surface mount capacitor, resistor, processor, etc.; vias for connectivity between layers; and contact pads. Consequently, the principles disclosed herein with respect to two levels 110, 112, and their associated first and second trace layers 206, 210, is readily expandable to as many layers and components as are needed to provide the desired electronic effect.

The collection of layers of the laminate structure may be referred to as a “stack”. A final or intermediate structure may be referred to as a layup, and may include at least one stack (or multiple stacks, e.g., using modular construction techniques) that has been unitized. A unitizing operation may involve steps performed to a stack to finalize the layup. In some cases, unitizing may occur as a structure is being assembled, for example while laying up a stack, or may occur once a structure has been assembled. Examples of unitizing operations include a combination of heat and/or pressure, such as heat pressing, curing in an oven, cold pressing, rolling, or the like. Additionally or alternatively, the structure could comprise one or more unitized stacks with at least one electronic component. A laminate assembly may comprise multiple laminate structures, e.g., in a modular construction. The assembly may utilize island architecture including a first laminate structure (the “island”), which may typically but not exclusively be itself a laminate structure populated with electric components, or a laminate structure that is, e.g., a discrete sensor, with the first laminate structure adhered to a second laminate structure including, e.g., traces and vias configured like a traditional printed circuit board (“PCB”), e.g., acting as the pathways for signals, currents or potentials to travel between the island(s) and other auxiliary structures, e.g., sensors.

Moreover, the lateral dimensions of the traces may be increased or decreased to change the electronic characteristic as desired. In the illustrated example of the electronic component 102, the traces provide a dimension of the three-dimensional inductor of nine (9) millimeters by 7.5 millimeters and an inductance of one hundred ten (110) nanoHenrys. The effective coil size may be defined by the layers 206, 212, where the width is apparent while the length is defined by the left coil trace of 206 and the right trace of 212. In the illustrated example, the right trace of 206 and left trace of 212 are longer due to the offset for vias 114. However, if additional inductance were desired from the electronic component 102 the number of trace layers may be increased with the channel 104 formed such that a resultant elongate conductive trace overlaps with the first and second elongate conductive traces 124, 126 in the two-dimensional projection, with an insulation layer 208 and vias 114 coupled between the additional trace layer(s) in an alternating pattern until the desired inductance is provided by the electronic component 102.

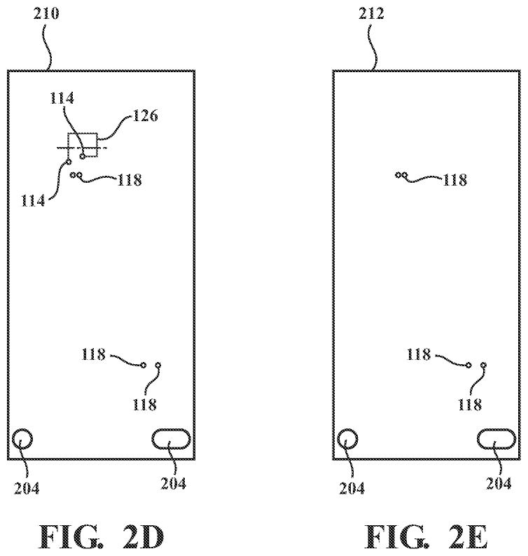

FIGS. 3A-3E are abstract depictions of routing patterns in patterned layers of a laminate structure, in an example embodiment. The laminate structure may be or may be part of an alternative electronic component different from the electronic component 102 in that the laminate structure includes at least five levels, with one level corresponding to one patterned layer of the stack of the laminate structure. The illustrations of FIGS. 3A-3E are thus intended only to illustrate abstract depictions of routing patterns of patterned layers in particular and, consequently, the laminate structure may incorporate additional layers not depicted in FIGS. 3A-3E but described herein, such as a substrate layer and multiple encapsulant layers, as needed to produce the desired laminate structure.

Moreover, it is to be recognized and understood that while the routing patterns are described with respect to patterned layers of a laminate structure, the routing patterns may be generated according to any other suitable manufacturing technique, including manufacturing techniques described herein with respect to the electronic component 102.

The routing patterns of FIGS. 3A-3E are thus to illustrate principles of routing patterns that may applied and combined to form laminate structures of more than the two layers of the electronic component 102. While five routing patterns are illustrated, the principles illustrated may be applied, e.g., iteratively to routing patterns of subsequent layers, to create extensible laminate structures having as many layers as desired or, more generally, electronic components with as many levels as desired to create an electronic component with a particular electronic effect. Each patterned layer may be provided with an insulation layer interposed between it and another patterned layer, whereby the insulation layer(s) may be provided with vias for operatively connecting various traces between two or more patterned layers. In general, the routing patterns illustrate one mechanism for hosting terminals on a single layer of the structure which may be used as interconnects to, e.g., another structure or electronic component.

FIG. 3A is a first routing pattern 302 and corresponds to the routing pattern of the first patterned layer 206. FIG. 3B is a second routing pattern 304 and generally corresponds to the routing pattern of the second patterned layer 210. FIG. 3C is a third routing pattern 306 that may be applied to a third patterned layer above the second patterned layer in a stack of a laminate structure. FIG. 3D is a fourth routing pattern 308 that may be applied to a fourth patterned layer above the third patterned layer in a stack of the laminate structure. FIG. 3E is fifth routing pattern 310 that may be applied to a fifth patterned layer.

In the illustrated examples, each of the routing patterns 302, 304, 306, 308, 310 has a common width 312 and a common length 314. It is noted that the terms “width” and “length” are applied arbitrarily but consistently for the purposes of illustration and description and that the terms should not be interpreted as limiting relative to any particular dimension or orientation of the routing patterns to the laminate structure overall, provided the terms are applied consistently among the routing patterns. Further, each of the routing patterns 302, 304, 306, 308, 310 have common gaps 316 between adjacent extents, e.g., 318, 320 of the traces of the routing patterns 302, 304, 306, 308, 310 (illustrated specifically with respect to FIG. 3A but it is to be understood the gaps 316 apply to all of the routing patterns 302, 304, 306, 308, 310). In various examples, the extents may correspond to vias and/or corners or other features of the routing patterns 302, 304, 306, 308, 310.

The stacked orientation of the routing patterns 302, 304, 306, 308, 310 establish a relationship between vias in each pattern. The first routing pattern 302 includes a first via 322 that extends to the second routing pattern 304. The second routing pattern 304 includes a second via 324 that extends to the third routing pattern 306. The third routing pattern 306 includes a third via 326 that extends to the fourth routing pattern 308. The fourth routing pattern 308 includes a fourth via 328 that extends to the fifth routing pattern 310. The fifth routing pattern 310 includes a fifth via 330 that extends to a sixth routing pattern, which is not depicted. The first routing pattern 302 further includes a through via 332 that extends to a top layer, which also is not depicted.

The routing patterns 302, 304, 306, 308, 310 consequently establish a framework for extending the laminate structure to a desired number of layers, i.e., by iteratively shifting the gap 316 in a clockwise direction around each routing pattern 302, 304, 306, 308, 310 as the routing pattern increases with each layer. Owing to the vertical vias, the gap 316 in each routing pattern 302, 304, 306, 308, 310 thus shifts by the length of the gap 316 from one routing pattern 302, 304, 306, 308, 310 to the next. However, it is to be recognized and understood that alternative examples of the laminate structure does not necessarily shift the gap 316 from in a clockwise manner or in a consistent manner between routing patterns 302, 304, 306, 308, 310. In various examples, the gaps 316 may shift in a counterclockwise pattern or by more than the width of one gap 316. However, in the example of irregular shifting of the gap 316 from layer to layer, the amount of each routing pattern 302, 304, 306, 308, 310 that is thus able to contribute to the electronic effect of the laminate structure may be reduced.

The routing patterns 302, 304, 306, 308, 310 do not include a top routing pattern, i.e., a layer above which a final encapsulant layer encapsulates the top routing pattern and beyond which is not included in the laminate structure, as illustrated with the encapsulant layer 212 in FIG. 2E in relation to the electronic component 102. In various examples, the top routing pattern may be an adapted version of one of the routing patterns 302, 304, 306, 308, 310 to provide a via that aligns with the through via 332 to electrically connect the top routing pattern with the first routing pattern 302.

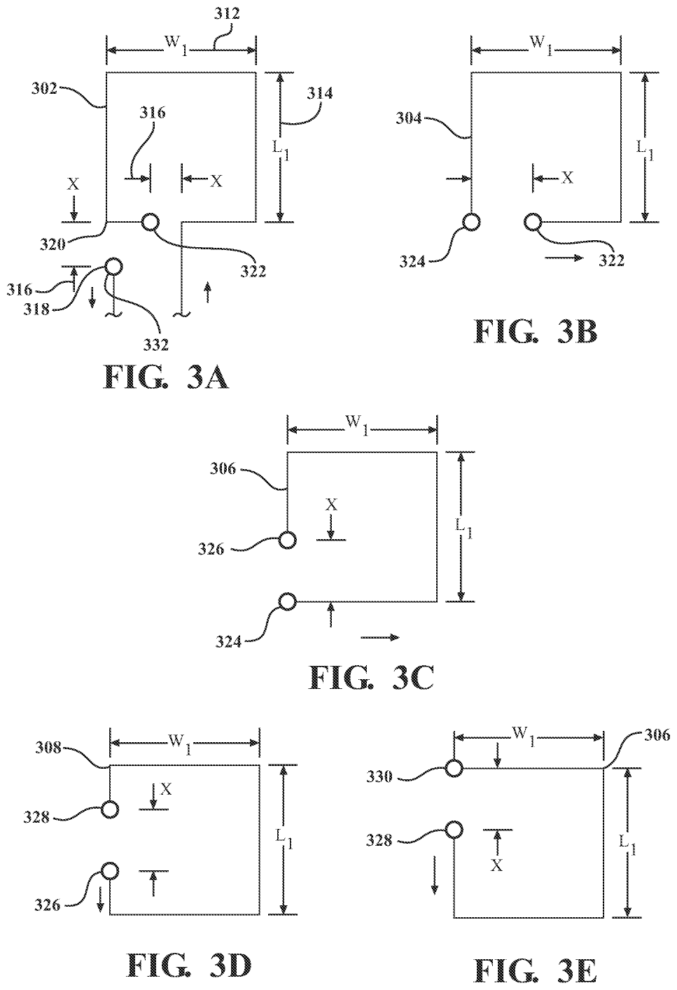

FIGS. 4A and 4B are abstract depictions of a bottom routing pattern 402 and a top routing pattern 404, respectively, in an example embodiment. The bottom routing pattern 402 is an adapted version of the first routing pattern 302 while the top routing pattern 404 is an adapted version of the fourth routing pattern 308, meaning that the resultant laminate structure would include the bottom routing pattern 402, the second routing pattern 304, the third routing pattern 306, and the top routing pattern 404, but not the first routing pattern 302, the fourth routing pattern 308, and the fifth routing pattern 310.

The bottom routing pattern 402 and the top routing pattern 404 generally align with the first routing pattern 302 and the fourth routing pattern 308, respectively, with the top routing pattern 404 adapted from the fourth routing pattern 308 to be the top routing layer and the bottom routing pattern 402 adapted from the first routing pattern 302 based on the changes made to the top routing pattern 404. The bottom routing pattern 402 thus includes the first via 322, the same width 312 and length 314 as well as the gap 316 as the first routing pattern 302. The top routing pattern 404 starts from the third via 326 and extending along first trace 406 and second trace 408 having the same width 312 and length 314 as the equivalent traces of the fourth routing pattern 308. However, third trace 410 and fourth trace 412 have a width and length, respectively, that is greater than those dimensions of the equivalent traces of the fourth routing pattern 308.

In general, variances in the dimensions of the traces from the top routing pattern 402 in comparison with the fourth routing pattern 308 may be attributable to the provision of the through via 332 aligned with and operatively coupled to the through via 332 of the first routing pattern 302. Consequently, it is to be recognized and understood that any particular routing pattern may be applied as the top routing pattern 402 provided that the through via 332 in the top routing pattern 402 aligns with the through via 332 and the top routing pattern 402 mimics the other routing patterns. Moreover, the configuration of the top routing pattern 402 assumes that the through via 332 is a vertical via, and that it is desirable to connect trace 410 to a trace in a different layer. Optionally, the trace 410 may continue elsewhere in a layer comprising the routing pattern 402, e.g., to a terminal in that layer.

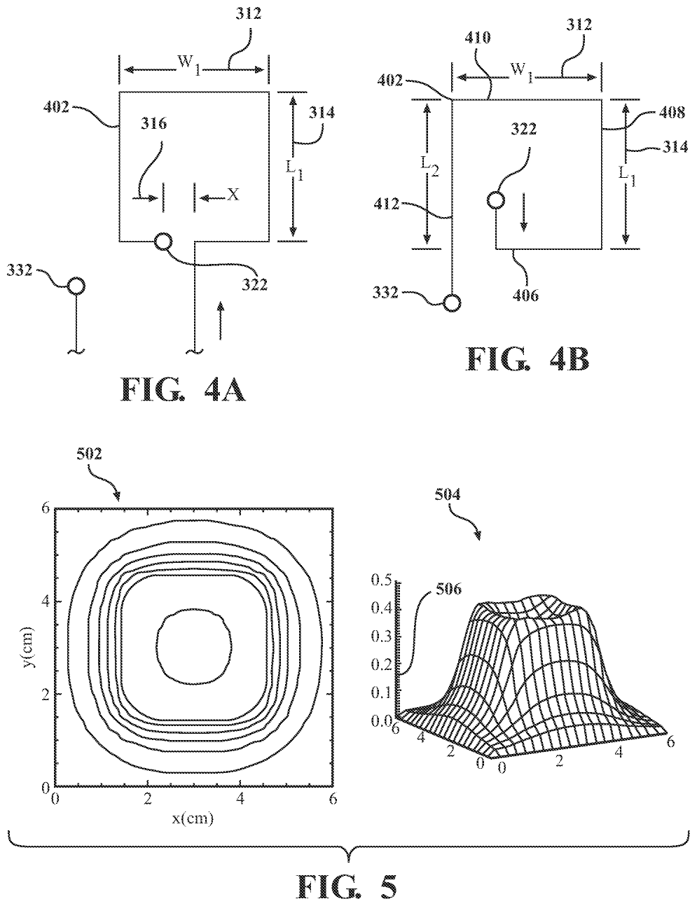

FIG. 5 is illustrations of a normalized magnetic field generated by the electronic component 102 when current is passed over the conductive gel 108, in an example embodiment. The illustrations include a heat map 502 and an isometric contour map 504. The heat map 502 is viewed along the major axis 116 of the electronic component 102. The major axis 116 aligns with the z-axis 506 of the isometric contour map 504.

It may be expected that the square coil electronic component 102 may have approximately the same magnetic field at its center of area, approximately the same sensitivity region, and a smaller inductance value in relation to a circular coil having the same area. However, the square coil implementation of the electronic component 102 may come with manufacturing advantages which in certain circumstances may make straight sides 122 relatively more cost effective to produce than curved channels 104 in a circular loop. Further, for the same characteristic dimension, for example a square coil having side lengths equaling the diameter of a circle, the square coil would have a higher magnetic field value, a larger sensitivity region, and a similar inductance value.

It should be appreciated that, while circular loops and square loops are contemplated herein, the loops may define any geometric shape that has an area bounded by the loop's geometry. In multi-level or multi-layer electronic components, each layer may have a loop geometry that defines the same shape, or one or more layers may host a loop having a different geometric shape. The area of the shape hosted on any given layer may have a center of area. It may be advantageous to stack the layers with the centers of area substantially aligned or overlaid, for example within a tolerance of about ten (10) percent of a characteristic dimension of the loop shape. The characteristic dimension may define the overall size of the shape and thereby the area of the shape, e.g., the characteristic dimension may be the larger of the shape's overall length or width. In one example, the characteristic dimension may be the diameter of a circular loop. Other examples include the longest side of a rectangle, the side of a square, or the overall length or width of an irregular shape. In any example, it may be advantageous that the characteristic length of all stacked shapes be similar, such as within about ten (10) percent. Each level or layer may have a loop shape that defines an area that is similar to the areas of shapes in other layers. For example, a median area may be calculated from all stacked shape areas of the component, and all the shape areas may be within a tolerance of about thirty (30) percent of the median area.

The deformable electrically conductive compositions, such as conductive gels, comprised in the articles described herein can, for example, may have a paste like or gel consistency that can be created by taking advantage of, among other things, the structure that gallium oxide can impart on the compositions when gallium oxide is mixed into a eutectic gallium alloy. When mixed into a eutectic gallium alloy, gallium oxide can form micro or nanostructures that are further described herein, which structures are capable of altering the bulk material properties of the eutectic gallium alloy.

As used herein, the term “eutectic” generally refers to a mixture of two or more

phases of a composition that has the lowest melting point, and where the phases simultaneously crystallize from molten solution at this temperature. The ratio of phases to obtain a eutectic is identified by the eutectic point on a phase diagram. One of the features of eutectic alloys is their sharp melting point.

The electrically conductive compositions can be characterized as conducting shear thinning gel compositions. The electrically conductive compositions described herein can also be characterized as compositions having the properties of a Bingham plastic. For example, the electrically conductive compositions can be viscoplastics, such that they are rigid and capable of forming and maintaining three-dimensional features characterized by height and width at low stresses but flow as viscous fluids at high stress. Thus, for example, the electrically conductive compositions can have a viscosity ranging from about 10,000,000 Pa*s to about 40,000,000 Pa*s under low shear and about 150 to 180 at high shear. For example under condition of low shear the composition has a viscosity of about 10,000,000 Pas, about 15,000,000 Pa*s, about 20,000,000 Pa*s, about 25,000,000 Pa*s, about 30,000,000 Pa*s, about 45,000,000 Pa*s, or about 40,000,000 Pa*s under conditions of low shear. Under condition of high shear the composition has a viscosity of about 150 Pas, about 155 Pa*s, about 160 Pa*s, 165 Pats, about 170 Pa*s, about 175 Pas, or about 180 Pa*s.

The electrically conductive compositions described herein can have any suitable conductivity, such as a conductivity of from about 2×10⁵ S/m to about 8×10⁵ S/m.

The electrically conductive compositions described herein can have ay suitable melting point, such as a melting point of from about −20° C. to about 10° C., about −10° C. to about 5° C., about −5° C. to about 5° C. or about −5°° C. to about 0° C.

The electrically conductive compositions can comprise a mixture of a eutectic gallium alloy and gallium oxide, wherein the mixture of eutectic gallium alloy and gallium oxide has a weight percentage (wt %) of between about 59.9% and about 99.9% eutectic gallium alloy, such as between about 67% and about 90%, and a wt % of between about 0.1% and about 2.0% gallium oxide such as between about 0.2 and about 1%. For example, the electrically conductive compositions can have about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy, and about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide.

The eutectic gallium alloy can include gallium-indium or gallium-indium-tin in any ratio of elements. For example, a eutectic gallium alloy includes gallium and indium. The electrically conductive compositions can have any suitable percentage of gallium by weight in the gallium-indium alloy that is between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

The electrically conductive compositions can have a percentage of indium by weight in the gallium-indium alloy that is between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

The eutectic gallium alloy can include gallium and tin. For example, the electrically conductive compositions can have a percentage of tin by weight in the alloy that is between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The electrically conductive compositions can comprise one or more micro-particles or sub-micron scale particles blended with the eutectic gallium alloy and gallium oxide. The particles can be suspended, either coated in eutectic gallium alloy or gallium and encapsulated in gallium oxide or not coated in the previous manner, within eutectic gallium alloy. The micro-or sub-micron scale particles can range in size from nanometer to micrometer and can be suspended in gallium, gallium-indium alloy, or gallium-indium-tin alloy. Particle to alloy ratio can vary and can change the flow properties of the electrically conductive compositions. The micro and nanostructures can be blended within the electrically conductive compositions through sonication or other suitable means. The electrically conductive compositions can include a colloidal suspension of micro and nanostructures within the eutectic gallium alloy/gallium oxide mixture.

The electrically conductive compositions can further include one or more micro-particles or sub-micron scale particles dispersed within the compositions. This can be achieved in any suitable way, including by suspending particles, either coated in eutectic gallium alloy or gallium and encapsulated in gallium oxide or not coated in the previous manner, within the electrically conductive compositions or, specifically, within the eutectic gallium alloy fluid. These particles can range in size from nanometer to micrometer and can be suspended in gallium, gallium-indium alloy, or gallium-indium-tin alloy. Particle to alloy ratio can vary, in order to, among other things, change fluid properties of at least one of the alloys and the electrically conductive compositions. In addition, the addition of any ancillary material to colloidal suspension or eutectic gallium alloy in order to, among other things, enhance or modify its physical, electrical or thermal properties. The distribution of micro and nanostructures within the at least one of the eutectic gallium alloy and the electrically conductive compositions can be achieved through any suitable means, including sonication or other mechanical means without the addition of particles. In certain embodiments, the one or more micro-particles or sub-micron particles are blended with the at least one of the eutectic gallium alloy and the electrically conductive compositions with wt % of between about 0.001% and about 40.0% of micro-particles, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40.

The one or more micro-or sub-micron particles can be made of any suitable material including soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes, or copper spheres, or a combination thereof, or any other material that can be wetted by the at least one of the eutectic gallium alloy and the electrically conductive compositions. The one or more micro-particles or sub-micron scale particles can have any suitable shape, including the shape of spheroids, rods, tubes, a flakes, plates, cubes, prismatic, pyramidal, cages, and dendrimers. The one or more micro-particles or sub-micron scale particles can have any suitable size, including a size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

The electrically conductive compositions described herein can be made by any suitable method, including a method comprising blending surface oxides formed on a surface of a eutectic gallium alloy into the bulk of the eutectic gallium alloy by shear mixing of the surface oxide/alloy interface. Shear mixing of such compositions can induce a cross linked microstructure in the surface oxides; thereby forming a conducting shear thinning gel composition. A colloidal suspension of micro-structures can be formed within the eutectic gallium alloy/gallium oxide mixture, for example as, gallium oxide particles and/or sheets.

The surface oxides can be blended in any suitable ratio, such as at a ratio of between about 59.9% (by weight) and about 99.9% eutectic gallium alloy, to about 0.1% (by weight) and about 2.0% gallium oxide. For example percentage by weight of gallium alloy blended with gallium oxide is about 60%, 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, about 95%, about 96%, about 97%, about 98%, about 99%, or greater, such as about 99.9% eutectic gallium alloy while the weight percentage of gallium oxide is about 0.1%, about 0.2%, about 0.3%, about 0.4%, about 0.5%, about 0.6%, about 0.7%, about 0.8%, about 0.9%, about 1.0%, about 1.1%, about 1.2%, about 1.3%, about 1.4%, about 1.5%, about 1.6%, about 1.7%, about 1.8%, about 1.9%, and about 2.0% gallium oxide. In embodiments, the eutectic gallium alloy can include gallium-indium or gallium-indium-tin in any ratio of the recited elements. For example, a eutectic gallium alloy can include gallium and indium.

The weight percentage of gallium in the gallium-indium alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

A eutectic gallium alloy can include gallium, indium, and tin. The weight percentage of tin in the gallium-indium-tin alloy can be between about 0.001% and about 50%, such as about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, or about 50%.

The weight percentage of gallium in the gallium-indium-tin alloy can be between about 40% and about 95%, such as about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, about 60%, about 61%, about 62%, about 63%, about 64%, about 65%, about 66%, about 67%, about 68%, about 69%, about 70%, about 71%, about 72%, about 73%, about 74%, about 75%, about 76%, about 77%, about 78%, about 79%, about 80%, about 81%, about 82%, about 83%, about 84%, about 85%, about 86%, about 87%, about 88%, about 89%, about 90%, about 91%, about 92%, about 93%, about 94%, or about 95%.

Alternatively or in addition, the weight percentage of indium in the gallium-indium-tin alloy can be between about 5% and about 60%, such as about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 49%, about 50%, about 51%, about 52%, about 53%, about 54%, about 55%, about 56%, about 57%, about 58%, about 59%, or about 60%.

One or more micro-particles or sub-micron scale particles can be blended with the eutectic gallium alloy and gallium oxide. For example, the one or more micro-particles or sub-micron particles can be blended with the mixture with wt % of between about 0.001% and about 40.0% of micro-particles in the composition, for example about 0.001%, about 0.005%, about 0.01%, about 0.05%, about 0.1%, about 0.2%, about 0.3%, about 0.4%, about 0.5%, about 0.6%, about 0.7%, about 0.8%, about 0.9%, about 1%, about 1.5%, about 2%, about 3%, about 4%, about 5%, about 6%, about 7%, about 8%, about 9%, about 10%, about 11%, about 12%, about 13%, about 14%, about 15%, about 16%, about 17%, about 18%, about 19%, about 20%, about 21%, about 22%, about 23%, about 24%, about 25%, about 26%, about 27%, about 28%, about 29%, about 30%, about 31%, about 32%, about 33%, about 34%, about 35%, about 36%, about 37%, about 38%, about 39%, or about 40. In embodiments the particles can be soda glass, silica, borosilicate glass, quartz, oxidized copper, silver coated copper, non-oxidized copper, tungsten, super saturated tin granules, glass, graphite, silver coated copper, such as silver coated copper spheres, and silver coated copper flakes, copper flakes or copper spheres or a combination thereof, or any other material that can be wetted by gallium. In some embodiments the one or more micro-particles or sub-micron scale particles are in the shape of spheroids, rods, tubes, a flakes, plates, cubes, prismatic, pyramidal, cages, and dendrimers. In certain embodiments, the one or more micro-particles or sub-micron scale particles are in the size range of about 0.5 microns to about 60 microns, as about 0.5 microns, about 0.6 microns, about 0.7 microns, about 0.8 microns, about 0.9 microns, about 1 microns, about 1.5 microns, about 2 microns, about 3 microns, about 4 microns, about 5 microns, about 6 microns, about 7 microns, about 8 microns, about 9 microns, about 10 microns, about 11 microns, about 12 microns, about 13 microns, about 14 microns, about 15 microns, about 16 microns, about 17 microns, about 18 microns, about 19 microns, about 20 microns, about 21 microns, about 22 microns, about 23 microns, about 24 microns, about 25 microns, about 26 microns, about 27 microns, about 28 microns, about 29 microns, about 30 microns, about 31 microns, about 32 microns, about 33 microns, about 34 microns, about 35 microns, about 36 microns, about 37 microns, about 38 microns, about 39 microns, about 40 microns, about 41 microns, about 42 microns, about 43 microns, about 44 microns, about 45 microns, about 46 microns, about 47 microns, about 48 microns, about 49 microns, about 50 microns, about 51 microns, about 52 microns, about 53 microns, about 54 microns, about 55 microns, about 56 microns, about 57 microns, about 58 microns, about 59 microns, or about 60 microns.

### EXAMPLES

Example 1 is an electronic component, comprising: a substrate portion forming a channel; conductive gel positioned within the channel and arranged to create an electronic effect of the electronic component, the conductive gel forming a first elongate conductive trace and a second elongate conductive trace, the first elongate conductive trace forming a pattern of the electronic component that is mimicked by the second elongate conductive trace, the first and second elongate conductive traces having a common two-dimensional projection along a major axis of the electronic component.

In Example 2, the subject matter of Example 1 includes, wherein the first elongate conductive trace overlaps the second elongate conductive trace along the major axis.

In Example 3, the subject matter of any one or more of Examples 1 and 2 includes, wherein the substrate portion forms a plurality of layers stacked with respect to one another, wherein the plurality of layers include a first trace layer and a second trace layer, wherein the first elongate conductive trace is contained within a portion of the channel contained within the first trace layer and the second elongate conductive trace is contained within a portion of the channel contained within the second trace layer.

In Example 4, the subject matter of any one or more of Examples 1-3 includes, wherein the plurality of layers comprises a via layer positioned between the first trace layer and the second trace layer, wherein the via layer includes a portion of the channel that forms a via extending between the first trace layer and the second trace layer and configured to electrically couple the first elongate conductive trace to the second elongate conductive trace.

In Example 5, the subject matter of any one or more of Examples 1-4 includes, wherein the channel forms a plurality of straight lines and right angles in the first and second trace layers.

In Example 6, the subject matter of any one or more of Examples 1-5 includes, the first and second elongate conductive traces form a curve.

In Example 7, the subject matter of any one or more of Examples 1-6 includes, wherein the electronic component is a three-dimensional inductor.

Example 8 is a laminate structure, comprising: a first layer comprising a first film; a second layer comprising a first pattern of traces formed from a conductive gel; a third layer comprising a second film; a fourth layer comprising a second pattern of traces formed from the conductive gel; a fifth layer comprising a third film; the first pattern of traces defining a first perimeter portion of a first geometric shape having a first two-dimensional area; the second pattern of traces comprising a defining a second perimeter portion of a second geometric shape having a second two-dimensional area; the first area having a value within 10% of the second area; a first gap defined in the first perimeter portion and a second gap defined in the second perimeter portion, the first and second gaps defining a remainder of the first and second geometric shapes, respectively; wherein the first and second patterns are in electrical communication with one another and configured such that an electric potential applied to the first pattern induces a current flow along the first and second perimeter portions in a same direction, and the first and second gaps are offset from one another.

In Example 9, the subject matter of Example 8 includes, wherein the first pattern comprises a terminus and the second pattern comprises an origin, the terminus and origin are overlaid and connected by a via in the third layer.

In Example 10, the subject matter of any one or more of Examples 8 and 9 includes that the first gap has a first length and the second gap has a second length, and the first gap length has a value within 25% of the second gap length

In Example 11, the subject matter of any one or more of Examples 8-10

includes, wherein the first and second geometric shapes have a characteristic dimension.

In Example 12, the subject matter of any one or more of Examples 8-11 includes, wherein the characteristic dimension is the largest dimension of the shape.

In Example 13, the subject matter of any one or more of Examples 8-12 includes, wherein the characteristic dimension is selected from the group consisting of a radius, an overall length, and an overall width.

In Example 14, the subject matter of any one or more of Examples 8-13 includes, wherein the first and second geometric shapes are the same.

In Example 15, the subject matter of any one or more of Examples 8-14 includes, wherein the first and second geometric shapes have centers of area overlaid within a tolerance of about 10% of the characteristic dimension.

In Example 16, the subject matter of any one or more of Examples 8-15 includes, wherein the second gap is offset along the second perimeter portion opposite the direction of current flow. In Example 17, the subject matter of any one or more of Examples 8-16

includes, wherein at least one of the first and second geometric shapes is a rectangle.

In Example 18, the subject matter of any one or more of Examples 8-17 includes, wherein at least one of the first and second geometric shapes is a square.

In Example 19, the subject matter of any one or more of Examples 8-18 includes, wherein at least one of the first and second geometric shapes is a circle.

In Example 20, the subject matter of any one or more of Examples 8-19 includes, wherein all the geometric shapes are within 30% of a median shape area.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Some portions of this specification are presented in terms of algorithms or symbolic representations of operations on data stored as bits or binary digital signals within a machine memory (e.g., a computer memory). These algorithms or symbolic representations are examples of techniques used by those of ordinary skill in the data processing arts to convey the substance of their work to others skilled in the art. As used herein, an “algorithm” is a self-consistent sequence of operations or similar processing leading to a desired result. In this context, algorithms and operations involve physical manipulation of physical quantities. Typically, but not necessarily, such quantities may take the form of electrical, magnetic, or optical signals capable of being stored, accessed, transferred, combined, compared, or otherwise manipulated by a machine. It is convenient at times, principally for reasons of common usage, to refer to such signals using words such as “data,” “content,” “bits,” “values,” “elements,” “symbols,” “characters,” “terms,” “numbers,” “numerals,” or the like. These words, however, are merely convenient labels and are to be associated with appropriate physical quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or any suitable combination thereof), registers, or other machine components that receive, store, transmit, or display information. Furthermore, unless specifically stated otherwise, the terms “a” or “an” are herein used, as is common in patent documents, to include one or more than one instance. Finally, as used herein, the conjunction “or” refers to a non-exclusive “or,” unless specifically stated otherwise.

What is claimed is:

1. An electronic component, comprising:
a substrate portion forming a channel;
conductive gel positioned within the channel and arranged to create an electronic effect of the electronic component, the conductive gel forming a first elongate conductive trace and a second elongate conductive trace, the first elongate conductive trace forming a pattern of the electronic component that is mimicked by the second elongate conductive trace, the first and second elongate conductive traces having a common two-dimensional projection along a major axis of the electronic component.

2. The electronic component of claim 1, wherein the first elongate conductive trace overlaps the second elongate conductive trace along the major axis.

3. The electronic component of claim 2, wherein the substrate portion forms a plurality of layers stacked with respect to one another, wherein the plurality of layers include a first trace layer and a second trace layer, wherein the first elongate conductive trace is contained within a portion of the channel contained within the first trace layer and the second elongate conductive trace is contained within a portion of the channel contained within the second trace layer.

4. The electronic component of claim 3, wherein the plurality of layers comprises a via layer positioned between the first trace layer and the second trace layer, wherein the via layer includes a portion of the channel that forms a via extending between the first trace layer and the second trace layer and configured to electrically couple the first elongate conductive trace to the second elongate conductive trace.

5. The electronic component of claim 3, wherein the channel forms a plurality of straight lines and right angles in the first and second trace layers.

6. The electronic component of claim 2, the first and second elongate conductive traces form a curve.

7. The electronic component of claim 1, wherein the electronic component is a three-dimensional inductor.

8. A laminate structure, comprising:
a first layer comprising a first film;
a second layer comprising a first pattern of traces formed from a conductive gel;
a third layer comprising a second film;
a fourth layer comprising a second pattern of traces formed from the conductive gel.
a fifth layer comprising a third film;
the first pattern of traces defining a first perimeter portion of a first geometric shape having a first two-dimensional area;
the second pattern of traces comprising a defining a second perimeter portion of a second geometric shape having a second two-dimensional area;
the first area having a value within 10% of the second area;
a first gap defined in the first perimeter portion and a second gap defined in the second perimeter portion, the first and second gaps defining a remainder of the first and second geometric shapes, respectively;
wherein the first and second patterns are in electrical communication with one another and configured such that an electric potential applied to the first pattern induces a current flow along the first and second perimeter portions in a same direction, and the first and second gaps are offset from one another.

9. The laminate structure of claim 8, wherein the first pattern comprises a terminus and the second pattern comprises an origin, the terminus and origin are overlaid and connected by a via in the third layer.

10. The laminate structure of claim 8, wherein the first gap has a first length and the second gap has a second length, and the first gap length has a value within 25% of the second gap length.

11. The laminate structure of claim 8, wherein the first and second geometric shapes have a characteristic dimension.

12. The laminate structure of claim 11, wherein the characteristic dimension is the largest dimension of the shape.

13. The laminate structure of claim 12, wherein the characteristic dimension is selected from the group consisting of a radius, an overall length, and an overall width.

14. The laminate structure of claim 8 wherein the first and second geometric shapes are the same.

15. The laminate structure of claim 11, wherein the first and second geometric shapes have centers of area overlaid within a tolerance of about 10% of the characteristic dimension.

16. The laminate structure of claim 8, wherein the second gap is offset along the second perimeter portion opposite the direction of current flow.

17. The laminate structure of claim 8, wherein at least one of the first and second geometric shapes is a rectangle.

18. The laminate structure of claim 8, wherein at least one of the first and second geometric shapes is a square.

19. The laminate structure of claim 8, wherein at least one of the first and second geometric shapes is a circle.

20. The laminate structure of claim 8, wherein all the geometric shapes are within 30% of a median shape area.
